(19) United States
(12) Patent Application Publication
(10) Pub. No.: US 2004/0128602 A1
(43) Pub. Date: Jul. 1, 2004

(54) Direct memory access with error correction

(76) Inventor: Michael Stewart Lyons, San Diego, CA (US)

Correspondence Address: MORRISON & FOERSTER LLP, 755 PAGE MILL RD, PALO ALTO, CA, 94304-1018, US

(21) Appl. No.: 10/661,098

(22) Filed: Sep. 12, 2003

Related U.S. Application Data
(60) Provisional application No. 60/414,500, filed on Sep. 27, 2002.

(51) Int. Cl. G06F 11/00; G01R 31/28

(52) U.S. Cl. 714/736

(57) ABSTRACT

A method, systems and/or computer program products for a memory controller having superior throughput and reduced latency with superior error correction and detection for data passing therethrough. Writeback to rewrite words having correctable errors is provided for with little or no impact on total system throughput rates.

### CROSS-REFERENCE TO RELATED APPLICATIONS

This application claims priority to provisional application No. 60/414,500 entitled “METHOD AND APPARATUS FOR INFORMATION STORAGE”, filed Sep. 27, 2002.

### STATEMENT REGARDING FEDERALLY SPONSORED RESEARCH OR DEVELOPMENT

Not applicable.

### REFERENCE TO A COMPACT DISK APPENDIX

Not applicable.

### FIELD OF THE INVENTION

This invention generally relates to information storage. The invention more specifically relates to interfaces for large arrays of semiconductors such as those useful for disk caching, and “solid state disk memories”.

### BACKGROUND OF THE INVENTION

Storage area networks with communicating devices intended primarily to provide non-volatile memory are commonplace. Devices include rotating disks, with or without semiconductor caches. Other devices are non-volatile, battery-backed semiconductor memories, optionally with magnetic storage backup such as rotating disk or magnetic tape.

In order to provide higher performance storage devices than those of previously developed solutions, extremely large arrays of semiconductor memories have been used in communicating storage devices on storage area networks. Existing protocols and access techniques typically used with semiconductor memories are not well adapted to the requirements of storage area network communications. Consequently, intelligent controller circuits are provided to supervise activities such as buffering, caching, error detection and correction, sequencing, self-testing/diagnostics, performance monitoring and reporting. In the pursuit of performance, such controllers preferably provide the fastest available data rates and the lowest achievable latency times. The highest performing controllers are of complex design incorporating more than one computing architecture, resulting in the need to pass data between multiple disparate digital electronic subsystems. Necessary synchronizing of disparate digital electronic subsystems has resulted in re-propagation, increased complexity or timing margins (and, in some cases, all of these), thus limiting overall performance (speed, error rates, reliability etc.) available within particular cost/price constraints.

The subject invention provides a superior tradeoff between cost, performance, complexity and flexibility for inter-subsystem interfacing with digital storage devices. The invention may also have wider application to other types of computer communication interfaces and/or networks.

### SUMMARY

Embodiments of the invention provide for non-volatile memory storage. Techniques are deployed to provide for superior tradeoffs in performance criteria, including but not limited to, cost, throughput, latency, capacity, reliability, usability, ease of deployment, performance monitoring, correctness validation, data integrity and so on.

According to an embodiment of the invention, a memory controller provides superior throughput and reduced latency with superior error correction and detection for data passing therethrough.

According to another aspect of an embodiment of the invention, a memory controller is provided that comprises: a Read FIFO (First-In/First-Out queue), a Write FIFO, a Writeback FIFO, a bidirectional I-O (input-output) port connected to a synchronous RAM (Random-Access Memory) array, a multiplexer operable to supply data to the I-O port, a command processor state machine block, an encoder block, an EDC (error detection and correction) block, and an address block.

According to another aspect of an embodiment of the invention, a method is provided that comprises receiving a request to read a block of consecutive words, addressing the array, initiating a read burst and iterating a transfer. In the absence of errors the transfer may comprise reading a word of data, confirming an absence of errors and placing a copy of the word of error-free data into a FIFO. If a correctable error occurs in the transfer, then this may involve reading a further word of data, detecting a correctable error, terminating the read burst, correcting the word, placing the corrected word into the FIFO, writing back the word into the array and recovering the transfer.

Other aspects of the invention are possible; some are described below.

### BRIEF DESCRIPTION OF THE DRAWINGS

The accompanying drawings, which are incorporated in and constitute a part of the specification, illustrate embodiments of the invention, and, together with the description, serve to explain the embodiments.

FIG. 1 is a block diagram of a solid-state file cache such as may be used to implement an embodiment of the invention.

FIG. 2 is an overall block diagram of an EFC FPGA according to an embodiment of the invention.

FIG. 3 is a state machine diagram for an EFC FPGA Main control according to an embodiment of the invention.

FIG. 4 is a state machine diagram for an extractor according to an embodiment of the invention.

FIG. 5 is a block diagram of a command processor block within an FPGA according to an embodiment of the invention.

FIG. 6 is a state machine diagram for a Command Processor according to an embodiment of the invention.

FIG. 7 is a block diagram of a Table RAM block within an FPGA according to an embodiment of the invention.

FIG. 8 is a state machine diagram for a DMA Read state machine according to an embodiment of the invention.

FIG. 9 is a state machine diagram for a DMA Write state machine according to an embodiment of the invention.

FIG. 10 is a block diagram of an EDC (Encoder/Decoder) block within an FPGA according to an embodiment of the invention.

FIG. 11 is a state machine diagram for an EDC state machine according to an embodiment of the invention.

FIG. 12 is a state machine diagram for an EDC Read state machine according to an embodiment of the invention.

FIG. 13 is a state machine diagram for an EDC Write state machine according to an embodiment of the invention.

For convenience in description, identical components have been given the same reference numbers in the various drawings.

### DETAILED DESCRIPTION

In the following description, for purposes of clarity and conciseness of the description, not all of the numerous components shown in the schematics and/or drawings are described. The numerous components are shown in the drawings to provide a person of ordinary skill in the art a thorough, enabling disclosure of the present invention. The operation of many of the components would be understood and apparent to one skilled in the art.

In various embodiments of the invention, structures and methods are provided for controlling a memory. One embodiment provides structures and methods for error correction and detection.

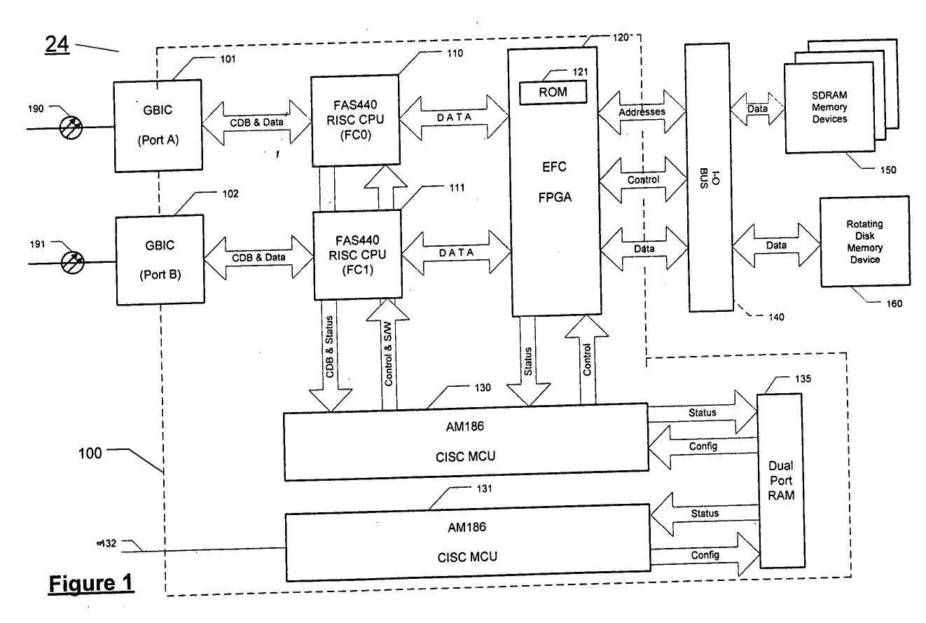

FIG. 1 is a block diagram of a solid state file cache 24 such as may be used to implement an embodiment of the present invention.

As shown in FIG. 1, a solid state file cache 24 may include a data controller 100 having one or more GBIC (Gigabit Interface Converter) circuits 101, 102 for communication using optical fiber links 190, 191 in compliance with a communication standard and protocol, for example, FCA. The various broad arrows in FIG. 1 represent data highways that may be implemented as multi-wire ports, interconnects and/or busses. The arrowheads indicate the direction of information flow along the data highways. As indicated, these data highways may carry Data, CDB (Command Descriptor Blocks), status information, control information, addresses and/or S/W (software images).

The data controller 100 may communicate with an I-O bus 140 to read and/or write data onto a HD (hard disk or rotating disk memory device) 160 and an array of one or more semiconductor memories such as SDRAMs (Synchronous Dynamic Random-Access Memories) 150. The SDRAMs 150 may typically be energized by batteries (electro-chemical cells, not shown in FIG. 1) so as to provide non-volatile memory storage up to the life of the batteries. The HD 160 may be interfaced using physical SCSI (Small Computer System Interface) and may be used to provide long term memory backup for indefinitely long periods, such as in the event of exhaustion or failure of the batteries.

Still referring to FIG. 1, data controller 100 may include one or more FCC ICs (Fibre-Channel controller integrated circuits) 110, 111 such as the FibreFAS440™ device from Qlogic® Corp. FibreFAS440™ devices include a RISC CPU (reduced instruction set computer processing unit). As is well known, RISC CPUs are well adapted to data-oriented computing tasks of relative simplicity but requiring very high speed. In the data controller 100, the program instructions, sometimes called microcode, may be downloaded from a CISC MCU (complex instruction set microcontroller unit) 130 such as the AM186 device from Applied Micro Devices® Inc.

As contrasted with RISC devices, CISC devices are slower, have a richer instruction set and support much larger memory address spaces of a more complex nature. They are well suited for use in implementing complex tasks that do not require the great achievable speed. The solid-state file cache 24 may include a second CISC MPU 131 which may communicate with the first CISC MPU 130 via a dual ported RAM (random-access memory) 135. CISC MPU 131 may provide for remote configuration management, monitoring and status reporting (RCM, RMR) and the like via an optional external interface (132) such as may be implemented using Ethernet, USB (universal serial bus) or EIA-232 (an Electronic Industry Association standard).

Still referring to FIG. 1, data controller 100 may further include a FPGA (field-programmable gate array) 120 for moving data in a controlled manner between FCC ICs 110, 111 and I-O bus 140. As depicted, FPGA 120 may include a ROM (read-only memory) 121 to direct its operation.

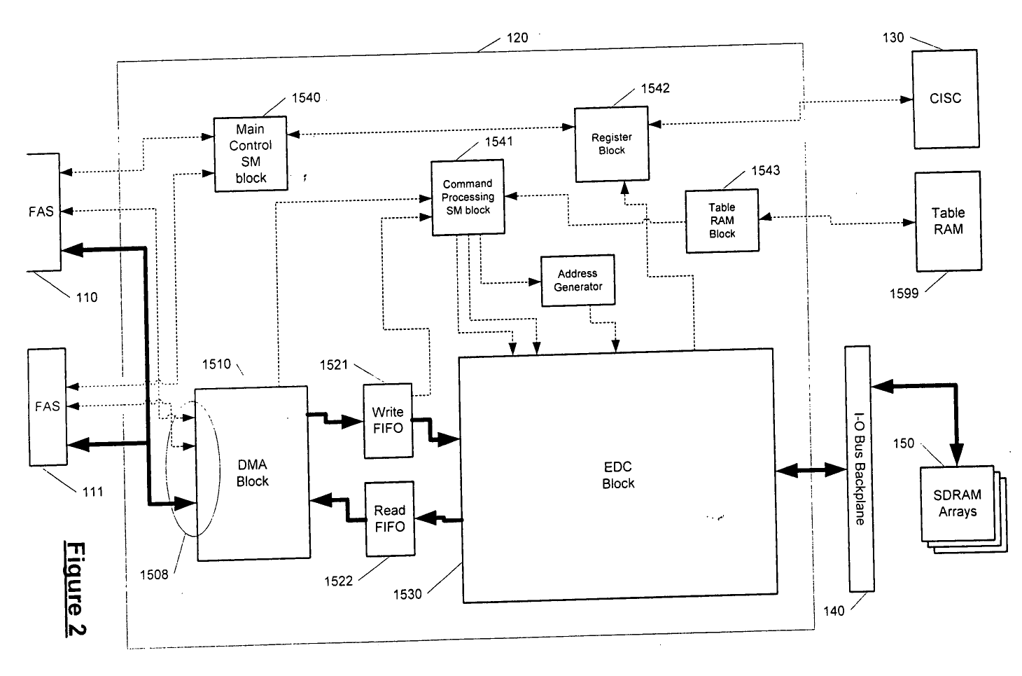

FIG. 2 shows, in block diagram form, an exemplary EFC (Embedded Fiber Controller) FPGA 120 according to an embodiment of the invention and some external connections thereto, for example, front-end FCC ICs 110, 111. Many of the EFC functions are embodied as SMs (Finite State Machines) as further discussed below.

In FIG. 2 solid connecting lines generally indicate data flows in the directions indicated by arrowheads. Dashed lines indicate flow of control information such as addresses, status lines or formatted command blocks. Shown within the EFC FPGA 120 are the DMA (Direct Memory Access) Interface 1508 and DMA block 1510, two internal FIFOs (First-In/First-Out queues) 1521, 1522, and an EDC (Error Detection and Correction) block 1530.

In the Write direction, the data may come in via the DMA interface 1508, go through the Write FIFO 1521, through the EDC block 1530, and out to the RAM array cards 150.

Conversely, in the Read direction the data may go through the Read FIFO 1522. Towards the top of FIG. 2 is the main control SM 1540 block (a hardware finite state machine). There is also a command processor SM block 1541, which performs data extraction from an FIU (Fibre-Channel Architecture Information Unit) that may be present in the information screen passing through the Write FIFO 1521.

Command processor block 1541 may be implemented as at least one SM, buffers, registers, etc. Register block 1542 is shown, which interfaces to CISC (complex instruction set computer) processor 130. Table RAM block 1543 may be interfaced to an internal or external Table RAM 1599 where stored may be address, address translation, LUN (Logical Unit Number) information and other information of the like.

An EFC FPGA 120, according to an embodiment of the invention, may act as an intermediary between certain transport interfaces and the SDRAM Array Card data storage 150. The transport interfaces, also called the front-end, may be comprised of one SCSI chip (not shown in FIG. 2) and two Fibre Channel chips 110, 111. The Array Cards 150 may consist of banks of SDRAM memory chips.

In an exemplary embodiment of the invention, there can be up to sixteen SDRAM Arrays Cards 150 having 526 MB, 1 GB, 2 GB, or 4 GB of storage each. In that exemplary embodiment of the invention, the front-end at the DMA Interface 1508 shares an 18 bit (16 data+2 parity) bidirectional bus which operates off of an 80 MHz synchronous clock. In the same embodiment the SDRAM Array Cards 150 use a 72 bit (64 data+8 parity) bidirectional bus which is referenced to a 40 MHz synchronous clock. Thus, the EFC FPGA 120 may reconcile the data rate difference between these two interfaces in terms of both bus width and clock frequency. In order to move data to or from the SDRAM Array Cards 150, the EFC FPGA 120 may generate address and several control signals. In addition, the EFC FPGA 120 performs Error Detection and Correction on all data read from the SDRAM Array Cards 150.

Pursuant to detecting an error in data read from SDRAM, a Write cycle may automatically be performed to write corrected data back to SDRAM. The EFC FPGA 120 also generates periodic refresh cycles that are required by the SDRAM to maintain its stored data.

An embodiment of the EFC FPGA 120 may provide command processing functionality. In order to decrease the access time of the system, the EFC FPGA 120 can process Read and Write commands that would be handled by a system processor (typically RISC or CISC) in previously developed solutions. Enabled by a system processor, this mode of the EFC FPGA 120 applies only to the Fibre Channel front-end chips. Commands other than Read and Write commands are interpreted by a system processor and not by EFC FPGA 120.

When a Fibre Channel chip receives a Read or Write command, it may use a dedicated output pin to signal the FPGA to read the command block. Once the EFC FPGA 120 has received the CDB (command descriptor block), it extracts several parameters. These may include the Source ID, the LUN (logical unit number), the Opcode, the LBA (logical block address), the Transfer Length, and the Data Length. The Source ID and LUN may be used to look up the appropriate SDRAM Array Card base address using a dedicated Table RAM that may be external to the EFC FPGA 120. Values may be loaded into the Table RAM by the system processor via store and forward registers.

Alternative embodiments may utilize different types of memory, such as ROM (Read-Only Memory) in place of Table RAM. The memory base address may be applied to the LBA and the resulting offset address sent to an SDRAM Array Card 150 as the actual SDRAM address. Prior to the start of a data cycle, at least two checks are typically done to ensure data integrity. First, the Transfer Length and Data Length are compared to make sure that they are compatible. Next, the sum of the Transfer Length and the actual address is compared to the highest possible address of the LUN to make sure that the data cycle will not operate outside of a permissible address range. If either of these checks fails, the data transfer is not started and an error interrupt or some other alert may be generated.

The data path in exemplary embodiments of the invention functions generally to flow data expeditiously with minimal intermediate storage. This may essentially act to minimize re-propagation delays. Thus, when a transfer begins, such as in a Read direction, a bank in the array card is opened, data pumping is started, and data flows through the whole path without stopping. Data flow may be slowed down in transit through the FIFOs but does not stop on a word basis. The interfaces may provide throttling, effects of which may be buffered by a FIFO. To slow a transfer down, the array cards may be paused, and consequently will eventually slow down average throughput, and possibly there may be an eventual need for restart addressing.

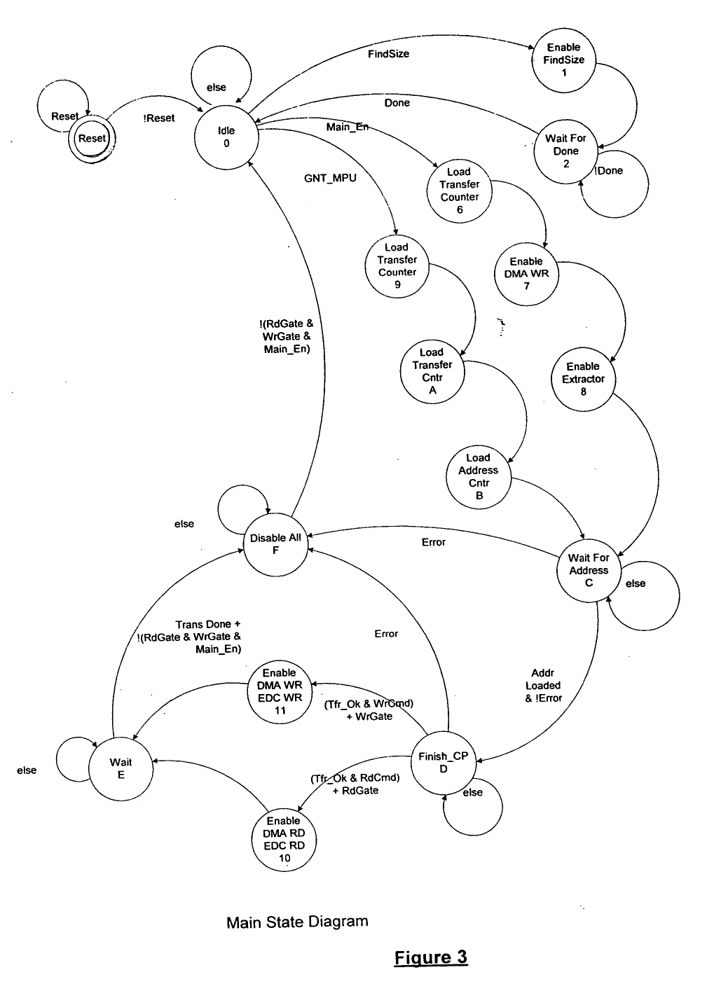

FIG. 3 (Main State Diagram B) depicts a state diagram for the Main Control SM according to an embodiment of the invention. The Main Control SM is in overall control as the name may suggest. It may start in Idle mode waiting for certain events. In the case of an automated transfer, a main enable may come from a prior state machine. Then a transfer counter may be loaded, DMA SMs enabled, the extracting SM enabled, and there may then be a Wait for an Address to be loaded. Responsive to whether a Read or a Write operation, one of two paths may be followed and there may be a Wait for completion. Once completed there may be a ‘Disable_all’ subset which is a cleanup mechanism. Thereafter, the Main Control SM may return to idle. Another path is provided for the MPU to use the SCSI backup channel. Few steps are needed because the MPU does most of them under its control. Thus, the backup channel is mostly not automated within EFC state machine, but rather under CISC program control.

Still referring to FIG. 3, the Main Control SM may operate as follows: The Main Control SM may control the EFC FPGA main path for data flow. When a Main_En signal is received from a Handshake SM, the Main Control SM may enable the DMA Write SM to transfer the FIU to the FPGA for processing. Once the Command Processing mechanisms have completed, the SM will transition to the Finish_CP state which does cleanup after the FIU transfer. It then Enables either the Read or Write datapath through the FPGA and waits for the transfer to complete. Once complete, it disables the datapath and returns to Idle.

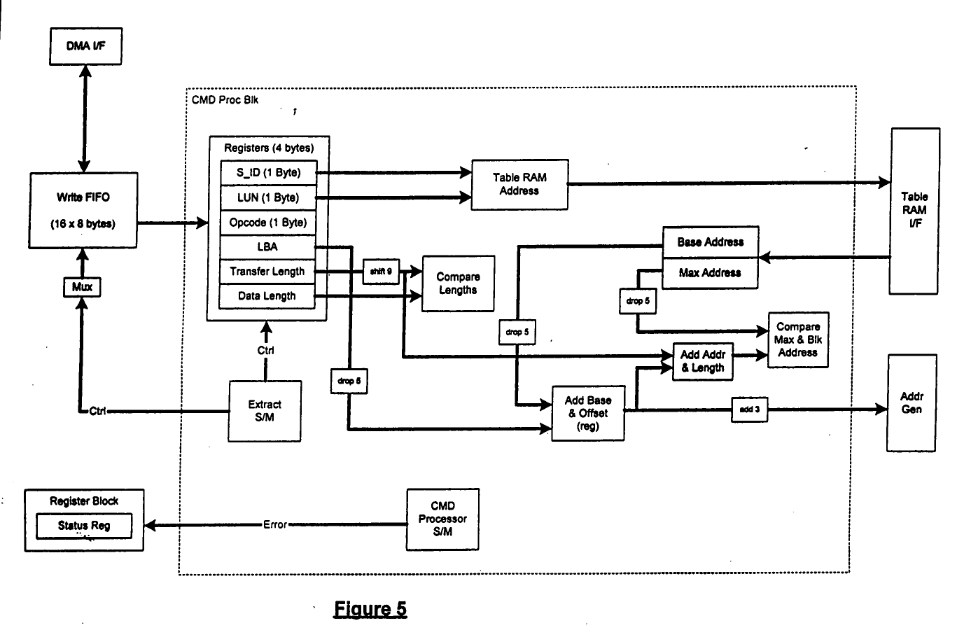

Referring to FIG. 5 an embodiment of Command Processing, which may be a major EFC FPGA subsystem, is depicted as CMD Proc Blk. In the embodiment depicted, whenever a command comes into a FibreFAS440, it will pull the command in to a DMA FIFO (not shown in FIG. 5), validate the Opcode to determine Read, Write, or other and then signal using a PortA0 signal that a command is coming.

Then an entire FlU (Fibre Information Unit) including CDB, LBA, and other parts enter the channel 0 DMA FIFO. Then the DREQ signal is asserted causing the FIU to be extracted. A DMA block transfer may be simulated and FIU may be placed in the write FIFO. The Command Processing block may take the data out of the FIFO, or alternatively the data may flow to the back end via the EDC.

There are two further state machines in the back end. One pulls data out from the FIFO and extracts it, including parsing parts of the data into registers. The other state machine may take the Source ID and the LUN to create an address into a Table RAM, supervise use of Table RAM for lookup, and decode maximum addresses for that applicable Source ID/LUN combination. This effectively provides a direct lookup-scaling algorithm.

The processor may set up the Table RAM with the entries that are needed. So the base and the maximum (limit) are taken and mathematics is performed on them, and then comparison follows. There are checks to prevent writing out of range and the like. Thus, command boundary checking may be done in the hardware, not in the software as in certain previously developed solutions. Algorithms may include well-known algorithms such as “dropping five” (which may be implemented as shift math). The transfer length and the data length may be mathematically operated on and then compared for transfer limit checking.

In previously developed solutions, typically there may be an inferior software function that takes several orders of magnitude more time. In previously developed solutions, such boundary checks can take a long time with such big words as are typical. Functions may be implemented in hardware with a register that may be 32-bits long. This may be non-trivial in software as with previously developed solutions.

A similar approach may be embodied as to base address. Base, offset, address and length may be operated on, and if in good order then the command processor state machine is permitted to do the transfer.

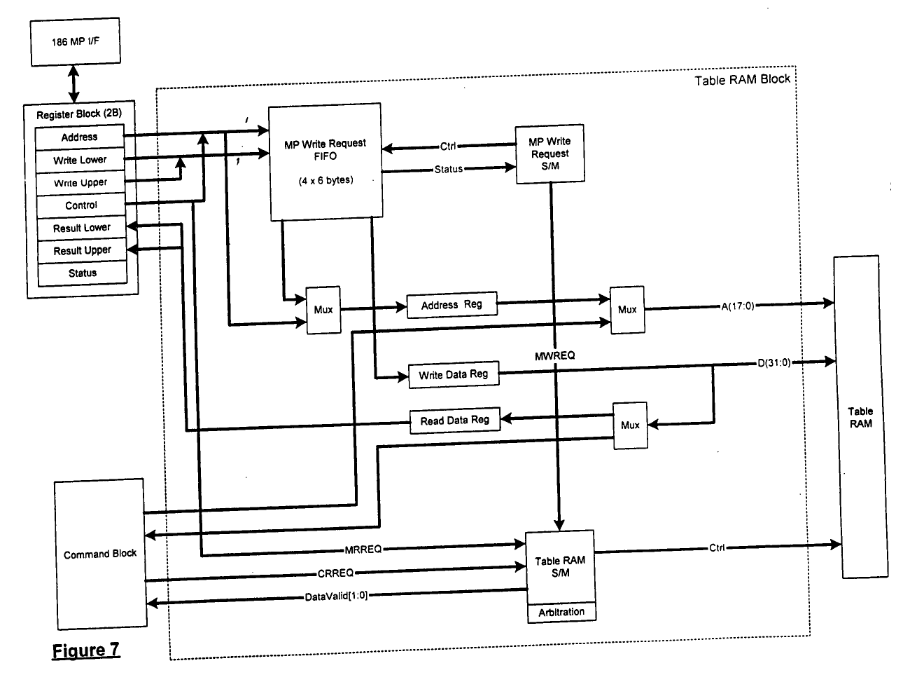

FIG. 7 depicts an exemplary Table RAM embodiment. A mechanism for accessing Table RAM may be provided. MPU software may write to the Table RAM, and hardware may read from the Table RAM under state machine control. An arbiter may be provided to resolve or alleviate conflicting accesses.

Still referring to FIG. 7, the state machine down at the bottom takes three different types of requests—a microprocessor write request, a microprocessor read request and a command processing read request. It may control which circuit gets access to the various entities. The MP Write request may take the Source ID address and data and queue them up in a FIFO, and then there may be a state machine that generates an action condition. The addresses may be selected, as well as the Write data for use in performing Writes, the Read register for reading back the data, etc. The register block may be that which the microprocessor can access. There may be 16-bit registers for address, upper and lower data, control, resulting data, status, etc. The processor may be involved. The command processing features are provided. They may send a Read request to the arbiter effectively conveying that data at a specified address is needed.

Once the command is decoded, internal registers are set up and handshaking with the 440 is performed to effectively convey that things check out correctly, and a transfer may be initiated. For a Read transfer, the 440 is set up and prepared for data, and data reading into a read FIFO may be started. If it is a Write transfer the converse may happen together with a wait for the channel 0 DMA FIFO to become full. Finally, there may be handshaking to conclude the transfer.

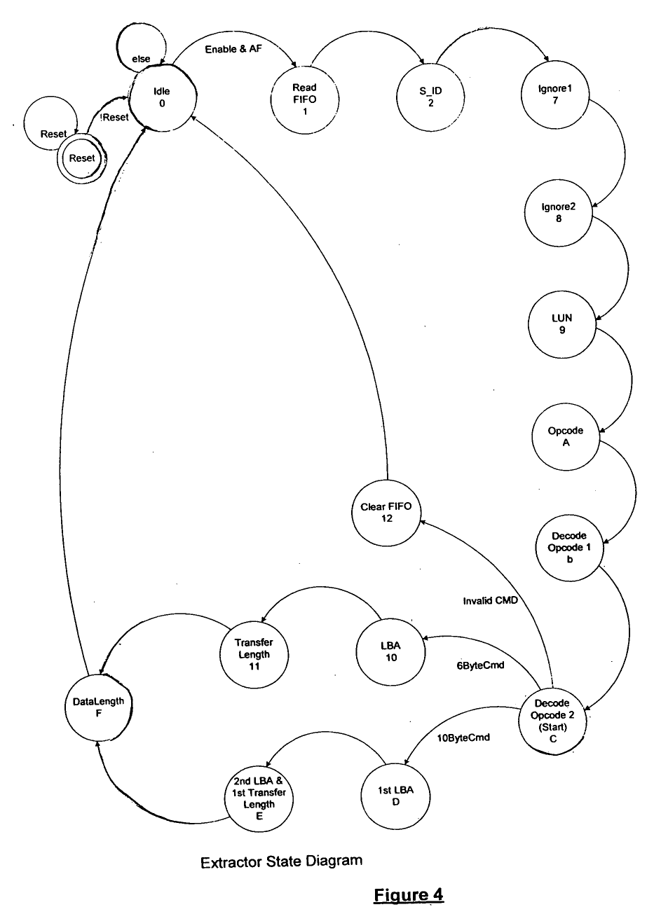

FIG. 4 (Extractor State Diagram A) depicts a state machine diagram for an Extracting SM according to an embodiment of the invention. Once the top level SM enables the Extracting SM, the latter waits for the write FIFO to fill up. Then the Extracting SM starts reading the FIFO, and isolates the Source ID, padding words, the LUN, the Opcode and so on. Thus, a command is parsed as a substantially atomic operation. A 10-byte/six-byte difference in CDB formatting may readily be handled by the Extracting SM.

Still referring to FIG. 4, the Extracting SM may operate as follows: The Extracting SM initially waits for the Write FIFO to fill up during a FIU transfer. The Extracting SM then starts reading the FIFO and extracts the necessary transfer information, for example, the Source ID, LUN, Opcode, LBA, Transfer Length, and Data Length. It branches from the Decode Opcode 2 state based on whether the SCSI command was 10-bytes or 6-bytes. It also starts the Command Processor State Machine from this state. Once finished, it may return to Idle.

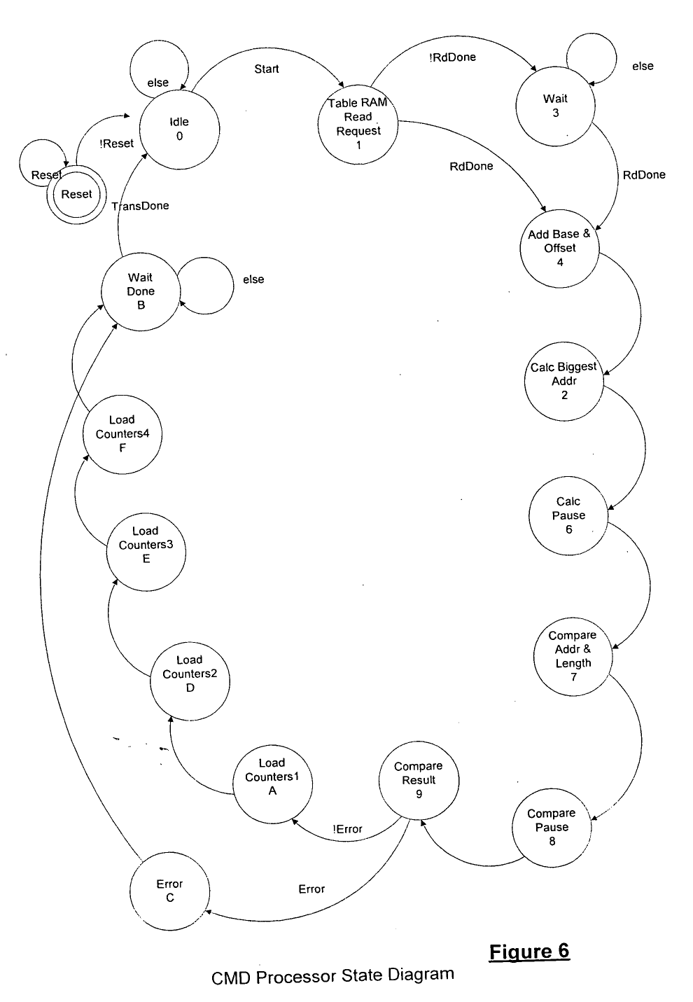

FIG. 6 (Command Processor State Diagram A) depicts a state machine diagram for a Command Processing SM. After initialization, a Start command comes from the Extracting SM. RAM requests are done, followed by a Wait until the information is provided. There is addition of the base address, calculation of address, comparison, and errors output where necessary. Then the address counters and the transfer counters are loaded, and the transfer is set up. Then there may be a Wait until the transfer is done.

Still referring to FIG. 6, the Command Processing SM operates as follows: Initially there are checks on the data extracted from the FIU. First the Base and Max Address are read from the Table RAM. This information is used to see if the upcoming transfer would violate the range prescribed for this particular Source ID) and LUN combination. If not, the Transfer Length and Data Length values are compared to make sure that they match. If all the checks pass, the SM loads the address and transfer counters throughout the FPGA in preparation for the upcoming transfer. It then waits for the transfer to complete before returning to Idle.

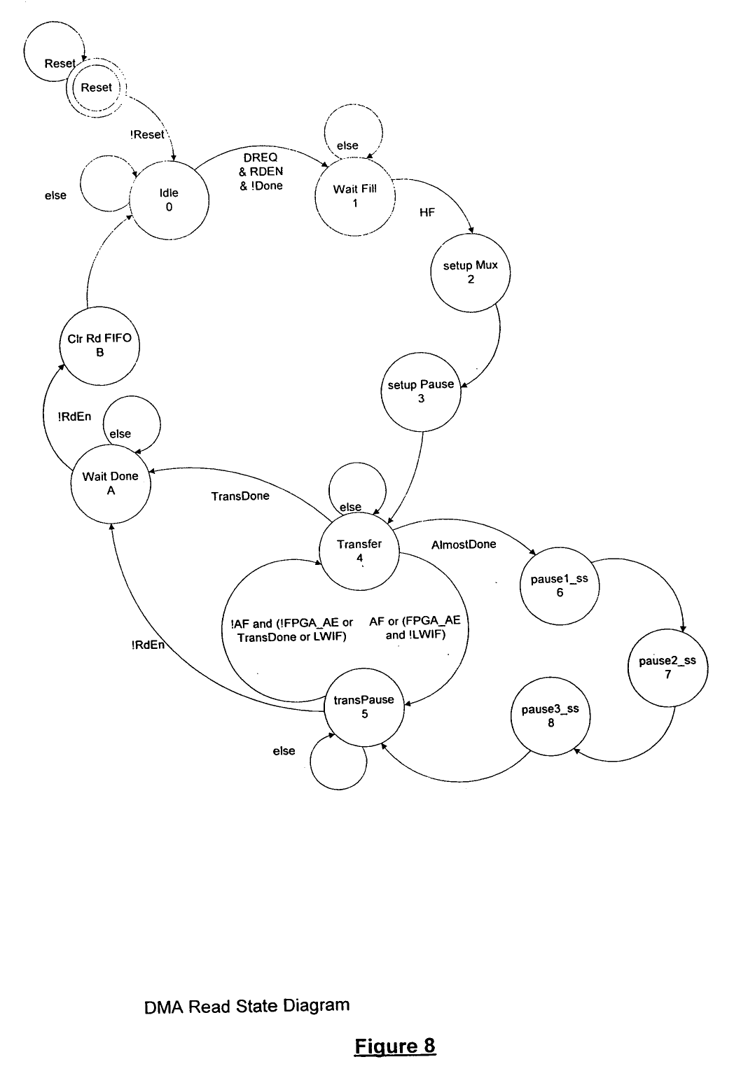

FIG. 8 (DMA Read State Diagram C) shows state diagrams for the Read DMA SM. Once enabled, there may be a wait for Read FIFO to become at least half full. Then a multiplexer may be set to switch the control signals and data bus to the appropriate subsystem, and a transfer commences. One path provides single stepping, to watch the flags from the 440/466 at the end of the transfer. There may be four states provided during wait for synchronization prior to continuation. If an error were to occur then there may be a cleanup activity.

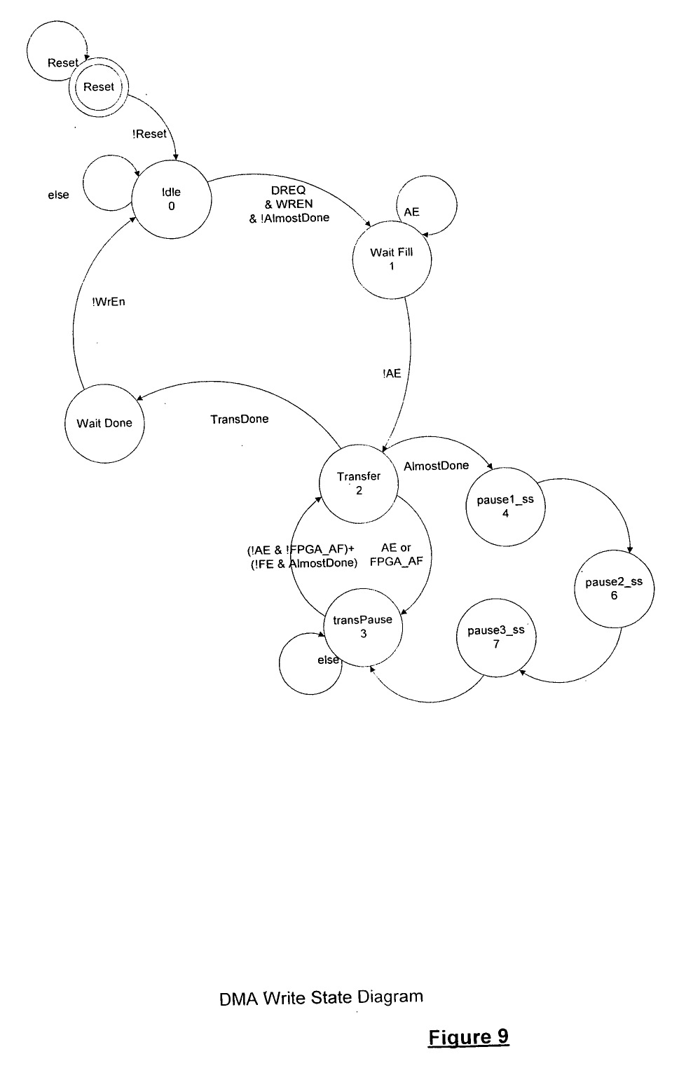

FIG. 9 (DMA Write State Diagram D) shows state diagrams for the Write DMA SM. Operation may be similar but complimentary to the Read DMA SM. In the Write DMA SM also there may be a wait for the 440/466 FIFO to fill up. Transferring, pausing, single step is all essentially comparable to the Read direction.

In an embodiment of the invention an EDC drives SDRAM at a width of 72 bits, consisting of 64 for data and a further 8 for redundancy checking. This provides high speed by use of RAM burst mode by eschewing more frequent address setups than may be found in previously developed solutions. Secondly the decoder provides for single bit error correction and multiple bit error detection on the fly without re-propagation, a big improvement over previously developed solutions. Also note that there are few stages, albeit with a great data width, and as a result transit delays are small, resulting in a large performance boost.

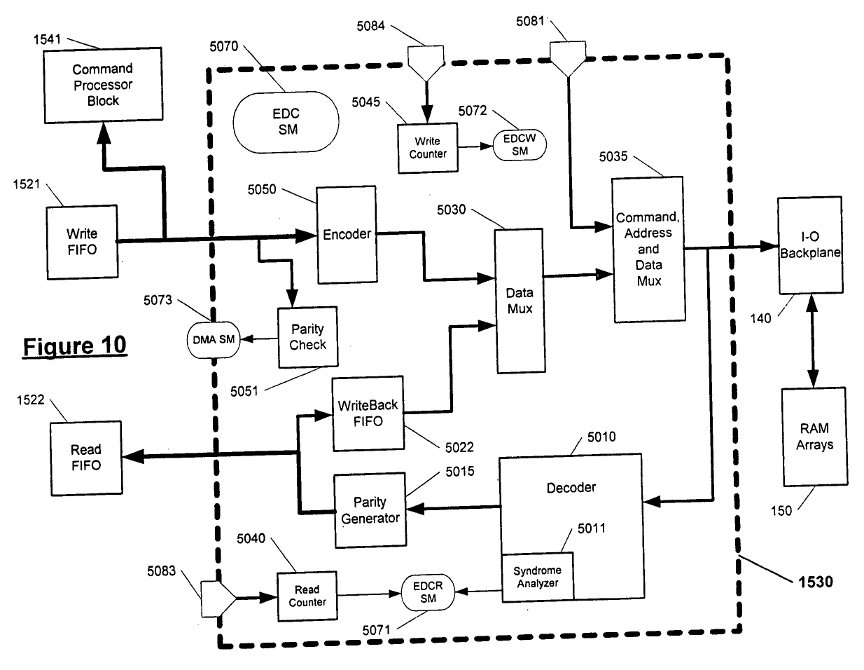

FIG. 10 is a block diagram of an EDC (Encoder/Decoder) block 1530 within an FPGA according to an embodiment of the invention. EDC block 1530 may be composed of combinatorial logic. In an embodiment of the invention very many gates within an FPGA were dedicated to this feature.

EDC block 1530 acts generally to convey data from Write FIFO 1521 to RAM Arrays 150 via I-O Backplane 140, and, conversely, to convey data from RAM Arrays 150 via I-O Backplane 140 to Read FIFO 1522.

The action of numerous blocks of an FPGA, including EDC block 1530, is controlled by SMs (finite state machines). Some of the SMs of the control EDC block 1530 are indicated in FIG. 10, such as EDCR SM 5071 (EDC-Read state machine), DMA SM 5073 (DMA state machine), and EDCW SM 5072 (EDC-Write state machine).

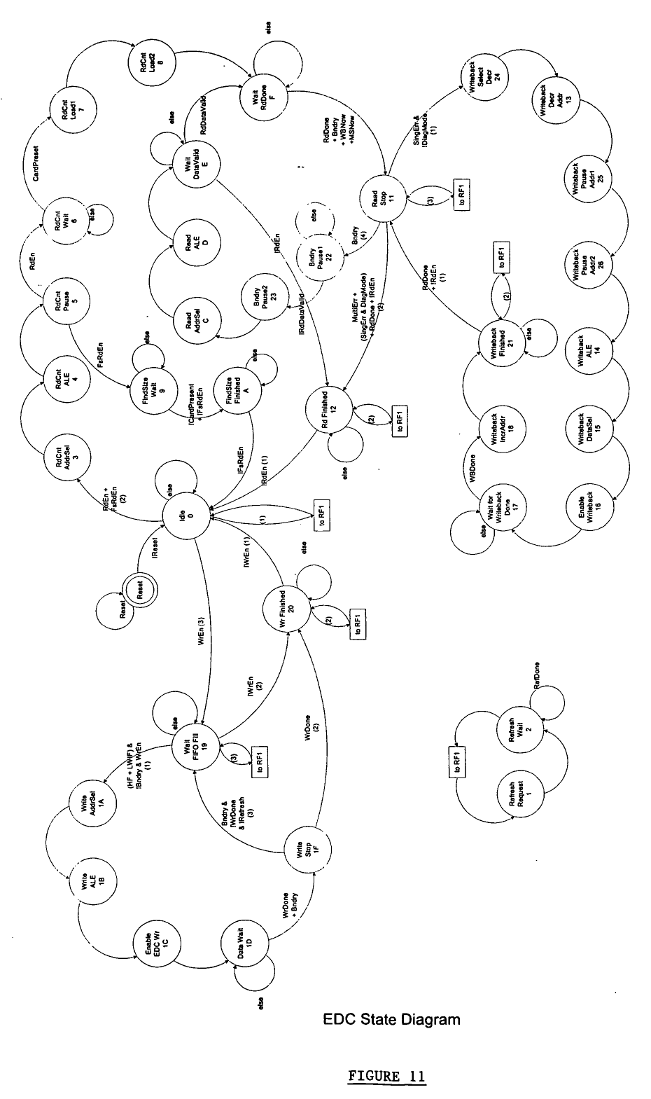

Overall operation of EDC block 1530 may be controlled by EDC state machine 5070 which receives various stimuli and controls other state machines within EDC block 1530. Operation of EDC state machine 5070 is described in connection with FIG. 11.

In an embodiment of the invention an EDC block 1530 drives SDRAM at a width of 72 bits, consisting of 64 for data and a further 8 for redundancy checking. This provides high speed by using SDRAM in burst mode, thus eschewing more frequent address setups that may be found in previously developed solutions.

EDC block 1530 may include Decoder 5010 which may provide for single bit error correction and multiple bit error detection on the fly without re-propagation, an improvement over previously developed solutions. Decoder 5010 may be implemented within an FPGA using combinatorial logic.

Since Decoder 5010 may be implemented using few stages, there may be only a small transit delay even where error correction takes place. Data leaving Decoder 5010 passes through Parity Generator 5015 which regenerates redundancy (parity) information so that data entering Read FIFO 1522 has correct parity even if (single bit) error correction has taken place. In an exemplary embodiment, data entering Parity Generator 5015 is 64 bits wide and data (including redundancy information) leaving Parity Generator 5015 is 72 bits wide.

Generally, the movement of data from I-O Backplane 140 through Decoder 5010 and Parity Generator 5015 to Read FIFO 1522 is performed under the control of a finite state machine, namely EDCR SM 5071.

Decoder 5010 may also include a Syndrome Analyzer 5011 which determines whether a data word passing through Decoder 5010 is error free, contains a single-bit corrected error, or contains detected multiple-bit detected errors. The output of Syndrome Analyzer 5011 may be connected to EDCR SM 5071. Occurrences of single-bit errors may typically indicate uncorrectable data error which may involve high-level recovery; the best the EDCR SM 5071 can do in such rare circumstances is to report the failure. Occurrences of single-bit errors may be correctable, however the EDCR SM 5071 may stop the transfer for write-back.

Read Counter 5040 may be programmed via port 5083 by another state machine within the FPGA but outside the EDC Block 1530. EDCR SM 5071 operates with Read Counter 5040 to determine completion and supervise of a Read transfer.

Data for writing to RAM enters EDC block 1530 from Write FIFO 1521. Parity Check 5051 validates data and alerts DMA SM 5073 in the event of an error. Encoder 5050 may generate redundancy information and data to be written to RAM Arrays 150 may pass through Data Mux (multiplexer) 5030, Command, Address and Data Mux 5035 and I-O Backplane 140.

Write FIFO conveys address and command information, in addition to data to be written to RAM Arrays 150. Address and Command information from Write FIFO 1521 passes to Command Processor Block 1541 which is within the FPGA but not part of EDC Block 1530. Command Processor Block 1541 operates as described in connection with FIG. 6 and causes RAM oriented commands and RAM oriented addresses to appear at port 5081 and so into Command, Address and Data Mux 5035.

Operation of Command, Address and Data Mux 5035 is under the control of EDCW SM 5072. EDCW SM 5072 uses Write Counter 5045 to determine end of data transfer. Write Counter 5045 is programmed by another part of the FPGA through port 5084.

FIG. 11 (EDC State Diagram F) depicts an EDC SM (Error detection and correction finite state machine) which may be relatively complex as contrasted with the other state machines in the EFC. This state machine controls the error detection and correction circuit and the interface to the SDRAM array cards. It consists of two major paths for the Read direction and Write direction, respectively.

The EDC may be implemented as hardware state machine(s) and combinatorial logic. The configurations of exemplary combinatorial logic useable for this purpose are shown in VHSIC (Very High Scale Integrated Circuit) format in Tables 1, 2 and 3 herein below.

In the EDC SM there may initially be an Idle state. Upon transfer action, the Main SM may signal the EDC SM to run and control the Back end of the microcircuit.

Still referring to FIG. 11, with Write enabled, there may be a wait for the write FIFO to half fill up. Then the address may be output onto the backplane and ALE asserted. Then a data select signals the array card that a write to a particular address is desired. The next state signals the lower state machine to actually do the transfer, that is the lower level functions. If a transfer completes it will cease. If a page boundary on the RAMs is hit, it will cease. If the Write is done, it resets, otherwise if on a boundary an inner loop is followed. There may be a Wait for the FIFO to fill before readdressing. Readdressing may be performed on each page boundary. If the transfer is smaller than a page transfer then readdressing may not occur.

Still referring to FIG. 11, consider the Read side of the circuit. This is more complex because, inter alia, error correction is provided. Once enabled, the multiplexer is selected to output an address onto the backplane and ALE (Address latch enable) may be asserted. Read_Enable may be a signal to an Array card FPGA to initiate a Read operation. There may be a wait for a signal from the array card to confirm that “The selected card exists and is ready for transfer operation.” Then there may be a wait for data from the selected array card. There may be a Read-data-valid condition implying valid data is presented on the bus at the moment. The actual transfer follows.

The transfer is stopped when completed, upon reaching a page boundary, or if a Writeback operation is needed in response to a soft error. Upon stopping several things may be checked according to the priority structure here. The first thing to happen could be a writeback, because that may have to happen immediately. So the counter is decremented, the address set up, ALE asserted, data select, and enable of the EDC Writeback state machine which is a lower state machine.

Writebacks may be done on a block-by-block basis because the Writeback FIFO may not be able to store an entire page. Thus, action may take place “on the fly” using a circular buffer. All the data that goes into the read FIFO also goes into this circular buffer. It will continue overwriting itself while holding a block's worth of data until it gets a flag conveying ‘a writeback is coming.’ Then it will be able to pump out the data via a lower state machine (for example, EDC Writeback State Machine (not shown in FIG. 11)).

When enabled, the address may be loaded where the block starts in the buffer and then begins the reading of the data out. When done it performs cleanup. When complete the array card address counter may be incremented back to where it formerly was. The second priority transition may be an EDC error, involving an exit and wait to be disabled. Another possibility is the transfer being done, so exit occurs. A fourth possibility is a refresh, discussed below. Another possibility may be merely a page boundary and continuation by pause, readdress, assert ALE, and cycle restart.

The only times refreshes occur may be at the end of transfers, at page boundaries, and upon stops to do writebacks. Refreshes should not get in the way of transfers so they are deferred a lot. A queue keeps track of how many are outstanding and then when at a good stopping point there may be a pause and continuation through all of the outstanding ones.

There is also a path for determining the sizes of RAM cards. It is outside the normal path.

Still referring to FIG. 7, when a Write Enable (WrEn) signal is received, the SM transitions from Idle to Wait FIFO Fill. Here it waits for the FPGA Write FIFO to fill up. Once it does, the SM puts the address on the backplane and enables the EDC Write State Machine. If a page boundary is encountered, the SM re-addresses the array card and continues the transfer.

When the transfer is complete the SM transitions to the WrFinished state and waits to be disabled.

When a Read Enable (RdEn) signal is received, the SM puts the address on the backplane and waits for a CardPresent signal from the selected array card. Once received, the SM transitions to Wait RdDone where it enables the EDC Read State Machine. It will transition to the Read Stop state if the transfer is done, if a bit error is detected, or if a page boundary is encountered. If a single-bit error is corrected by the error correction circuitry, the SM enters the Writeback loop, which writes the corrected block of data back to the array card. The SM re-addresses the array card and the transfer continues once this is complete. If a page boundary is encountered, the SM re-addresses the array card and continues the transfer. When the transfer is complete, the SM transitions to the Rd Finished state and waits to be disabled.

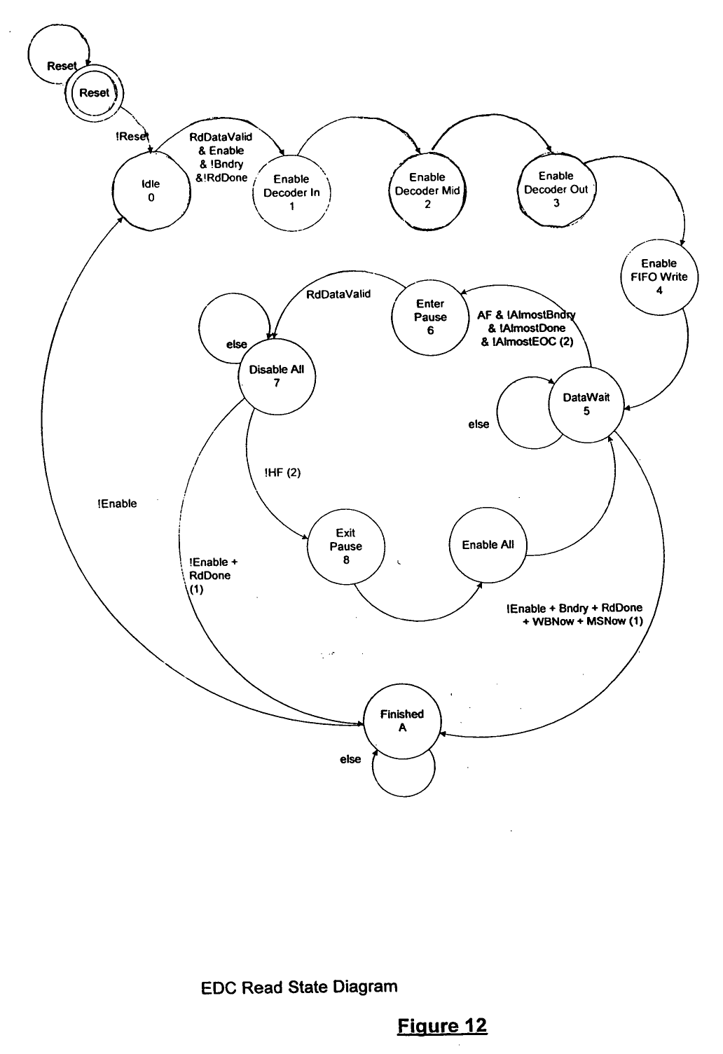

FIG. 12 depicts the underlying state machine for the read direction (EDC Read State Diagram B). Once enabled, the decoder is enabled, the analyzer is enabled and it checks the syndrome bits to notify whether there is no error or a single-bit or multi-bit error. Also the appropriate FIFO is enabled.

Thus, the analyzer is an error correction component using straight combinational logic. There may be a wait while data transfers. Exit if the FIFO is almost full, almost at a page boundary, almost done, etc. That provides a pausing mechanism.

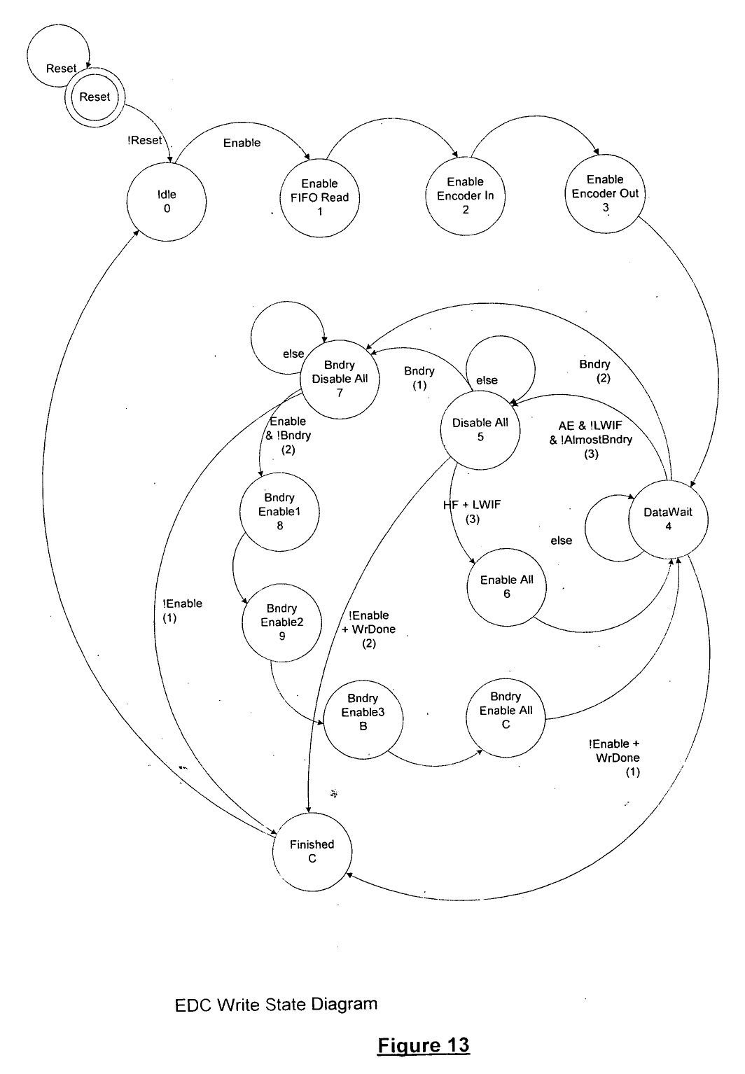

FIG. 13 depicts another lower level state machine (EDC Write State Diagram B). Data is moved by this state machine. Once enabled, there may be a Read of the Write FIFO. The encoder in and the encoder out are enabled. The first word of data may be stepped through the encoder pipeline so it does not get held up. Then there may be a spin with strobe asserted, to signal the array card of the actual data writing. The array card FPGA handles it from this point onwards. If a situation occurs wherein the FIFO becomes almost empty, or if the transfer is nearly done, or if data is near a boundary, then control transfers to the EDC state machine, and the array cards are paused. The page is not closed, merely paused. An implementation challenge may arise from the potentially variable backplane delays. Message passing with the array card FPGA is performed so there may be coasting rather than an abrupt stop involved.

Once the FIFO starts to fill up again, or if near the end of the transfer, completion and finish up occurs. If a boundary is hit, there may be a disable all, and then continuation, completion and cleanup.

FIG. 13 is a state machine diagram for an EDC Write state machine according to an embodiment of the invention. The EDC Write State Diagram will now be described.

This state machine controls the flow of data between the FPGA Write FIFO and SDRAM array cards in the Write direction. Once enabled, it begins reading from the FPGA Write FIFO. Next, the data is stepped through the encoder pipeline and out onto the backplane. In the Data Wait state, data is being sent to the SDRAM array cards. Should the FPGA Write FIFO become almost empty, or if it reaches a page boundary, then the SM will transition to Disable All to pause the transfer. Once these conditions are removed, the SM will transition back to Data Wait to continue the transfer. When the transfer is complete, it will transition to Idle.

Although embodiments of the present invention have been described in detail hereinabove, it should be clearly understood that many variations and/or modifications of the basic inventive concepts herein taught which may appear to those skilled in the present art will still fall within the spirit and scope of the present invention, as defined in the appended claims.

TABLE 2
Analyzer Configuration Expressed in VHSIC.

-- Error Analyzer Block
-- Solid Data Systems Inc.
--
-- This block takes the syndrome and analyzes it to determine the number
-- of errors detected or corrected.
library ieee;
use ieee.std_logic_1164.all;
entity analyzer is port (

| | |
|---|---|
| Clk | : in std_logic; -- system clock |

| Reset | : in std_logic; -- system reset |
|---|---|
| Syndrome | : in std_logic_vector(7 downto 0); |
| Enable | : in std_logic; |
| WritebackOff : in std_logic; | |
| RdDone | : in std_logic; |
| AlmostDone | : in std_logic; -- almost done indication |
| AlmostEOC | : in std_logic; -- almost end of chunk indication |
| Fast_Single | : out std_logic; |
| Mid_Single | : out std_logic; |
| Single | : out std_logic; |
| Fast_Multi | : out std_logic; |
| Mid_Multi | : out std_logic; |
| Multi | : out std_logic |
| ); | |

end analyzer;
--------------------------------------------------------------------------
architecture rtl of analyzer is

| | |
|---|---|
| constant zero_8 | : std_logic_vector(7 downto 0) := “00000000”; |
| signal s | : std_logic_vector(7 downto 0); |
| signal n_single | : std_logic; |

| | |
|---|---|
| signal n_multi | : std_logic; |
| signal n2_single | : std_logic; |

| | |
|---|---|
| signal n2_multi | : std_logic; |

begin

s <= Syndrome;

---------------------------------------------------------------------

| | |
|---|---|
| -- | logic: process (s, WritebackOff, Enable) |
| -- | logic: process (s, Enable, AlmostDone, AlmostEOC) |
| | logic: process (s, Enable, RdDone) |
| | begin |

| | |
|---|---|
| -- | if (WritebackOff = ‘1’ or Enable = ‘0’) then |
| -- | if (Enable = ‘0’) then |
| -- | if (Enable = ‘0’ or (AlmostDone = ‘1’ and AlmostEOC = ‘1’)) then |
| | if (Enable = ‘0’ or RdDone = ‘1’) then |

n_single <= ‘0’;
n_multi <= ‘0’;

elsif (s = zero_8) then -- if s = 0 then no error

n_single <= ‘0’;
n_multi <= ‘0’;

elsif ( (s(0) xor s(1) xor s(2) xor s(3) xor s(4) xor s(5) xor s(6) xor s(7)) =

‘0’) then

-- if s has even # of

ones then double error (detected)

n_single <= ‘0’;
n_multi <= ‘1’;

| | |
|---|---|
| else | -- if neither of above, then single |

error (corrected)

n_single <= ‘1’;
n_multi <= ‘0’;

end if;

end process;

---------------------------------------------------------------------
latches: process(Clk, Reset)

-- Latch these flags so that can gate them off with RdDone. This handles the case of

getting

-- an error in the first ‘extra word’ of a read.

begin

if (Reset = ‘1’) then

| | n2_single | <= ‘0’; |
|---|---|---|
| -- | n2_single | <= ‘1’; |
| | n2_multi | <= ‘0’; |

elsif (rising_edge(Clk)) then

| | n2_single | <= n_single; |
|---|---|---|
| -- | n2_single | <= ‘1’; --for test |
| | n2_multi | <= n_multi; |

end if;

end process latches;
---------------------------------------------------------------------
output_latches: process(Clk, Reset, RdDone)
begin

-- Latch these flags a second time so that glitches created by RdDone and n_switching at

the

-- same time don't cause reg_blk edge sensitive registers to trigger.
if (Reset = ‘1’) then

| | |
|---|---|
| Single | <= ‘0’; |
| Multi | <= ‘0’; |

elsif (rising_edge(Clk)) then

| | |
|---|---|
| Single | <= n2_single and not RdDone; |
| Multi | <= n2_multi and not RdDone; |

end if;

end process output_latches;
---------------------------------------------------------------------

-- concurrent statements
Fast_Single <= n_single;

-- Fast_Single error flag must be combinational in order to be asserted fast enough
-- to stop edc_sm to do writeback before it continues reading in the next block.
-- See notebook 9/18/01.

Mid_Single <= n2_single and not RdDone;

-- Mid_Single error flag must be gated but doesn't have time to go through another

flop.

-- It needs to get to edc_sm fast enough to confirm that it needs to do writeback.

Fast_Multi <= n_multi;

-- Fast_Multi error flag must be combinational in order to be asserted fast enough
-- to stop edc_sm before it continues reading in the next block. To stop bad data

from

-- being sent to host, must stop on same block.
-- Copied single circuitry. 7/16/02

Mid_Multi <= n2_multi and not RdDone;

-- Mid_Single error flag must be gated but doesn't have time to go through another

flop.

-- It needs to get to edc_sm fast enough to confirm that it needs to do multi-stop.

---------------------------------------------------------------------
end rtl;
---------------------------------------------------------------------
configuration cfg_analyzer of analyzer is

for rtl end for;

end cfg_analyzer;

TABLE 3
Encoder Configuration Expressed in Virtual Hardware Definition Language.

-- Encoding Block
-- Solid Data Systems
--
-- This block calculates the checkbits for the data to be written to SDRAM.
--
library ieee;
use ieee.std_logic_1164.all;
entity encoder is port (

| | |
|---|---|
| Clk | : in std_logic; -- system clk |

| | |
|---|---|
| Reset | : in std_logic; -- system reset |

| | |
|---|---|
| Data_In | : in std_logic_vector (63 downto 0); -- incoming data |

| | |
|---|---|
| EncodeEnIn | : in std_logic; -- enable incoder in |
| EncodeEnOut | : in std_logic; -- enable incoder out |

| | |
|---|---|
| Clr | : in std_logic; -- strobe to clear encoder latches |

| | |
|---|---|
| Data_Out | : out std_logic_vector (71 downto 0) -- outgoing codeword (data & |

checkbits)

);

end encoder;
------------------------------------------------------------------------
architecture rtl of encoder is

| | |
|---|---|
| signal u | : std_logic_vector(63 downto 0); -- incoming data |

(latched)

| | |
|---|---|
| signal DataBits | : std_logic_vector(63 downto 0); -- incoming data (2nd latch) |

| | |
|---|---|
| signal v | : std_logic_vector(7 downto 0); -- checkbits |

out of combination logic

| | |
|---|---|
| signal ChkBits | : std_logic_vector(7 downto 0); -- checkbits |

(latched)
begin
---------------------------------------------------------------------

latches: process (Clk, Reset, Clr)
begin

if (Reset = ‘1’or Clr = ‘1’) then

u <= (others => ‘0’);
ChkBits <= (others => ‘0’);
DataBits <= (others => ‘0’);

elsif (rising_edge(Clk)) then

if (EncodeEnIn = ‘1’) then

u <= Data_In;

end if;
if (EncodeEnOut = ‘1’) then

ChkBits <= v;
DataBits <= u; -- latch data a second time to line-up with chkbits

end if;

end if;

end process;
---------------------------------------------------------------------

-- combinational encoding (checked 7/26/00)
v(0) <= (

u(0) xor u(1) xor u(2) xor u(3) xor u(4) xor u(5) xor u(6) xor u(7) xor
u(12) xor u(13) xor u(14) xor u(15) xor u(20) xor u(21) xor u(22) xor
u(23) xor u(28) xor u(29) xor u(33) xor u(34) xor u(36) xor u(40) xor
u(44) xor u(48) xor u(52) xor u(56)
);

v(1) <= (

u(0) xor u(1) xor u(2) xor u(3) xor u(8) xor u(9) xor u(10) xor u(11) xor
u(12) xor u(13) xor u(14) xor u(15) xor u(24) xor u(25) xor u(26) xor
u(27) xor u(30) xor u(31) xor u(33) xor u(34) xor u(37) xor u(41) xor
u(45) xor u(49) xor u(53) xor u(57)
);

v(2) <= (

u(2) xor u(3) xor u(8) xor u(9) xor u(10) xor u(11) xor u(16) xor u(17) xor
u(18) xor u(19) xor u(20) xor u(21) xor u(22) xor u(23) xor u(28) xor
u(29) xor u(30) xor u(31) xor u(38) xor u(42) xor u(46) xor u(50) xor
u(54) xor u(58) xor u(61) xor u(62)
);

v(3) <= (

u(0) xor u(1) xor u(4) xor u(5) xor u(6) xor u(7) xor u(16) xor u(17) xor
u(18) xor u(19) xor u(24) xor u(25) xor u(26) xor u(27) xor u(28) xor
u(29) xor u(30) xor u(31) xor u(39) xor u(43) xor u(47) xor u(51) xor
u(55) xor u(59) xor u(61) xor u(62)
);

v(4) <= (

u(1) xor u(2) xor u(4) xor u(8) xor u(12) xor u(16) xor u(20) xor u(24) xor
u(32) xor u(33) xor u(34) xor u(35) xor u(36) xor u(37) xor u(38) xor
u(39) xor u(44) xor u(45) xor u(46) xor u(47) xor u(56) xor u(57) xor
u(58) xor u(59) xor u(62) xor u(63)
);

v(5) <= (

u(1) xor u(2) xor u(5) xor u(9) xor u(13) xor u(17) xor u(21) xor u(25) xor
u(32) xor u(33) xor u(34) xor u(35) xor u(40) xor u(41) xor u(42) xor
u(43) xor u(44) xor u(45) xor u(46) xor u(47) xor u(52) xor u(53) xor
u(54) xor u(55) xor u(60) xor u(61)
);

v(6) <= (

u(6) xor u(10) xor u(14) xor u(18) xor u(22) xor u(26) xor u(29) xor u(30)

xor

u(32) xor u(33) xor u(36) xor u(37) xor u(38) xor u(39) xor u(48) xor
u(49) xor u(50) xor u(51) xor u(52) xor u(53) xor u(54) xor u(55) xor
u(60) xor u(61) xor u(62) xor u(63)
);

v(7) <= (

u(7) xor u(11) xor u(15) xor u(19) xor u(23) xor u(27) xor u(29) xor u(30)

xor

u(34) xor u(35) xor u(40) xor u(41) xor u(42) xor u(43) xor u(48) xor
u(49) xor u(50) xor u(51) xor u(56) xor u(57) xor u(58) xor u(59) xor
u(60) xor u(61) xor u(62) xor u(63)
);

---------------------------------------------------------------------

Data_Out(7 downto 0) <= ChkBits;
Data_Out(71 downto 8) <= DataBits;

end rtl;
---------------------------------------------------------------------
configuration cfg_encoder of encoder is

for rtl end for;
end cfg_encoder;

What is claimed as new and desired to be protected by Letters Patent of the United States is:

1. A method for accessing data comprising the acts of:
receiving a request to read a block of consecutive words from an array of synchronous random access memory;
addressing the array;
initiating a first read burst from the array;
iterating a transfer, the transfer comprising the acts of:
reading a word of error-free data from the array, the word of data containing error detection redundancy bits;
confirming an absence of errors in the word of error-free data by performing an error detection algorithm upon the word; and
placing a copy of the word of error-free data into a FIFO;
reading a further word of data from the array;
detecting a correctable error in the further word of data;
terminating the first read burst;
correcting the further word to form a corrected word;
placing a first copy of the corrected word into the FIFO;
writing a further copy of the corrected word into the array;
initiating a second read burst from the array; and
further iterating the transfer, whereby the request is honored.

2. The method of claim 1 wherein the correctable error is a single bit error.

3. The method of claim 1 wherein the terminating is performed in response to the detecting.

4. The method of claim 1 wherein the terminating is performed after the detecting and prior to any further reading.

5. A memory storage device controller comprising:
a Read FIFO;
a Write FIFO;
a Writeback FIFO;
a bidirectional port connected to a synchronous RAM array, the synchronous RAM array operable to respond to commands;
a multiplexer operable to supply data to the port;
a command processor having an input operable to receive data from the Write FIFO, the command processor further operable to supply formatted RAM commands to the multiplexer;
an encoder having an input operable to receive data from the Write FIFO and to supply encoded data to the multiplexer;
an EDC (error detection and correction) block having an input operable to receive data from the port and further having an output operable to supply data to the Read FIFO and Writeback FIFO, the EDC block, the EDC block operable to correct correctable data errors and to detect uncorrectable data errors; and
an address block controlled by the command processor, the address block operable to supply addresses to the multiplexer.

6. The memory storage device controller of claim 5 further comprising:
a direct memory access (DMA) controller operable to supply data to the Write FIFO and to receive data from the Read FIFO.

7. The memory storage device controller of claim 5 wherein:
the encoder and the EDC block are state machines.

8. The memory storage device controller of claim 7 wherein:
the command processor, the encoder, and the EDC block are each part of a respective field programmable gate array.

9. The memory storage device controller of claim 7 wherein the memory storage device controller is in a single field programmable gate array.

10. The memory storage device controller of claim 9 wherein the address block is a table RAM.

11. The memory storage device controller of claim 1 wherein the address block is a table RAM.
